(19) United States
(12) Patent Application Publication
(10) Pub. No.: US 2011/0090660 A1
(43) Pub. Date: Apr. 21, 2011

(54) PRINTED CIRCUIT BOARD

(75) Inventor: CHIA-YUN LEE, Tu-Cheng (TW)

(73) Assignee: HON HAI PRECISION INDUSTRY CO., LTD., Tu-Cheng (TW)

(21) Appl. No.: 12/608,956

(22) Filed: Oct. 29, 2009

(30) Foreign Application Priority Data
Oct. 16, 2009 (CN) 200910308356.0

(51) Int. Cl. H05K 7/00

(52) U.S. Cl. 361/782; 361/783

(57) ABSTRACT

A printed circuit board includes a board body, a number of filtering capacitors, and a chip. The board body includes a chip mount area. The chip mount area includes a first area and a second area. The first and second areas each include a number of pads. The second area is surrounded by the first area. The pads of the second area are electrically connected to pins of the number of filtering capacitors. The pads of the first area are electrically connected to pins of the chip. The number of filtering capacitors is sandwiched between the chip and the second area.

### BACKGROUND

1. Technical Field

The present disclosure relates to a printed circuit board.

2. Description of Related Art

Surface mount technology (SMT) filtering capacitors of a traditional printed circuit board are placed on a reverse of the printed circuit board, to electrically connect to electronic elements of the obverse of the printed circuit board via via-holes of the printed circuit board. However, this kind of arrangement will bring long connection wires between the filtering capacitors and the electronic elements. Filter characteristics of the filtering capacitors may be reduced for effects of the equivalent series inductance (ESL) of the via-holes of the printed circuit board.

### BRIEF DESCRIPTION OF THE DRAWINGS

FIG. 1 is a schematic diagram of an exemplary embodiment of a printed circuit board including a board body.

FIG. 2 is similar to FIG. 1, but showing capacitors arranged on the board body.

FIG. 3 is similar to FIG. 1, but showing a chip arranged on the board body.

### DETAILED DESCRIPTION

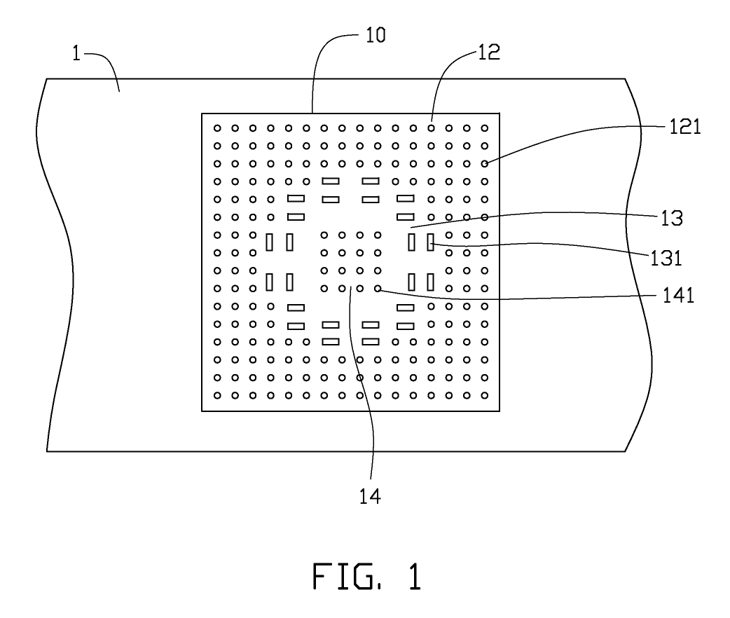

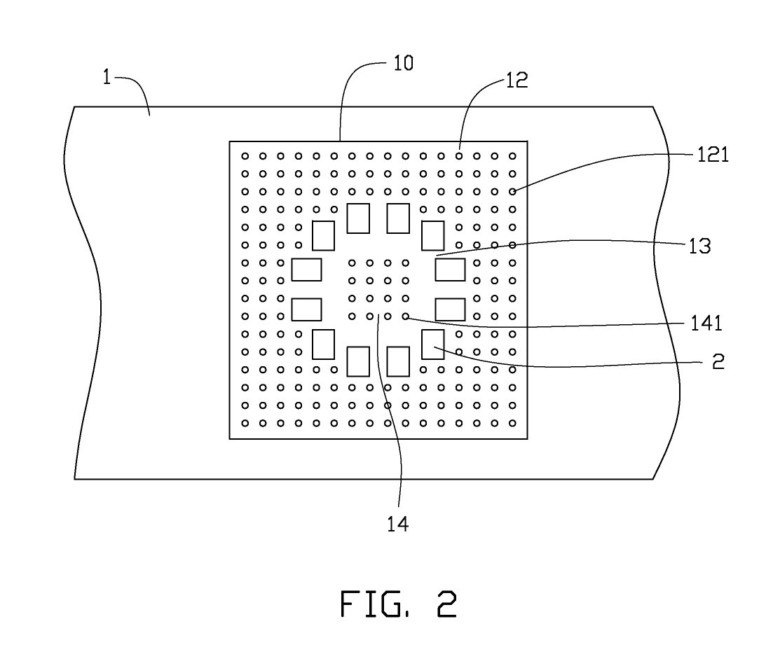

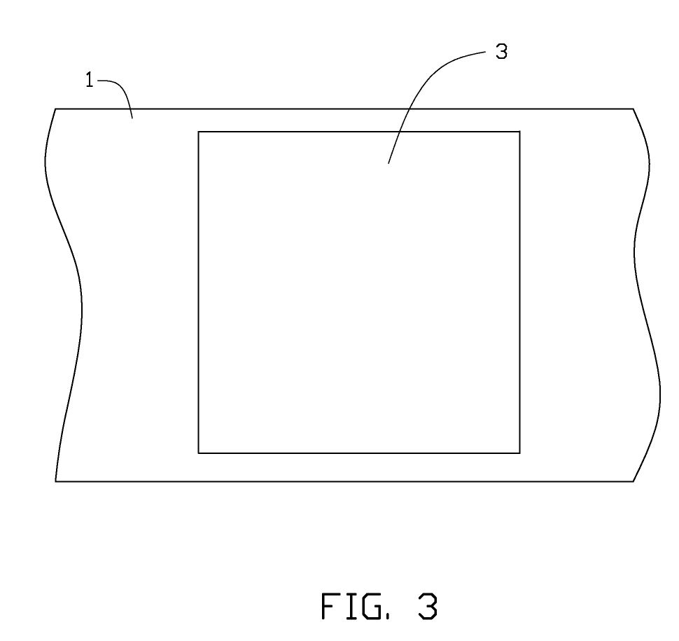

Referring to FIG. 1 to FIG. 3, an exemplary embodiment of a printed circuit board includes a board body 1, a plurality of filtering capacitors 2, and a chip 3.

The board body 1 includes a substantially square-shaped chip mount area 10. In one embodiment, the package technology of the chip 3 is ball grid array (BGA) package technology. The chip mount area 10 includes a first area 14 in a center of the chip mount area 10, a second area 13 surrounding the first area 14, and a third area 12 surrounding the second area 13. A plurality of pads 141, 131, and 121 are respectively set on the first area 14, the second area 13, and the third area 12. The plurality of pads 131 of the second area 13 are used for electrically connecting to pins of the plurality of filtering capacitors 2. The plurality of pads 141 of the first area 14 and the plurality of pads 121 of the third area 12 are used for electrically connecting to pins of the chip 3. Array location of the first area 14, the second area 13, and the third area 12 can be designed according to different chips. One of the first area 14 and the third area 12 can be deleted according to need.

In assembly, the pins of the chip 3 are electrically connected to the plurality of pads 141 and 121 of the first area 14 and the third area 12. The plurality of filtering capacitors 2 are located between the chip 3 and the chip mount area 10 of the board body 1, with pins of the plurality of filtering capacitors 2 electrically connected to the plurality of pads 131 of the second area 13.

In one embodiment, the chip 3 is a peripheral component interconnection express (PCIE) controller, and the type of the chip 3 is EP2432. The package size of the plurality of filtering capacitor 2 is 0201, and a height of each filtering capacitor 2 is about 0.3 millimeters. A height of the pins of the chip 3 is about 0.6 millimeters. When the chip 3 is mounted to the chip mount area 10 of the board body 1, due to jointing, a distance between a surface of the chip 3 with the pins and the chip mount area 10 of the board body 1 is about 0.45 millimeter. Therefore, the chip 3 can be correctly mounted to the chip mount area 10, and the plurality of filtering capacitors 2 are located between the chip mount area 10 and the chip 3. The printed circuit board can not only save space of the print circuit board, but also shorten the connection wires between the plurality of filtering capacitors 2 and the chip 3. Therefore, the printed circuit board improves filter characteristics of the plurality of filtering capacitors 2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others skilled in the art to utilize the disclosure and various embodiments and with various modifications as are suited to the particular use contemplated. Alternately embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising:
a plurality of filtering capacitors;
a chip; and
a board body comprising:
a chip mount area comprising:
a first area comprising a plurality of first pads; and
a second area comprising a plurality of second pads; wherein the second area is surrounded by the first area, the plurality of second pads of the second area are electrically connected to pins of the plurality of filtering capacitors, the plurality of first pads of the first area are electrically connected to pins of the chip, the plurality of filtering capacitors is arranged between the second area and the chip.

2. The printed circuit board of claim 1, wherein package technology of the chip is ball grid array package technology.

3. The printed circuit board of claim 1, wherein the chip mount area is substantially square-shaped.

4. A printed circuit board comprising:
a plurality of filtering capacitors;
a chip; and
a board body comprising:
a first area comprising a plurality of first pads;
a second area comprising a plurality of second pads; and
a third area comprising a plurality of third pads, wherein the second area surrounds the first area, and the third area surrounds the second area, the plurality of filtering capacitors is mounted on the second area via pins of the plurality of filtering capacitors electrically connected to the plurality of second pads of the second area, the chip is mounted on the first and third areas via pins of the chip electrically connected to the plurality of first and third pads, to sandwich the plurality of filtering capacitors with the second area.

5. The printed circuit board of claim 4, wherein package technology of the chip is ball grid array package technology.
